(19) United States
(12) Patent Application Publication
(10) Pub. No.: US 2025/0027191 A1
(43) Pub. Date: Jan. 23, 2025

(54) APPARATUS FOR MANUFACTURING DISPLAY APPARATUS, METHOD OF MANUFACTURING DISPLAY APPARATUS, AND MASK ASSEMBLY

(71) Applicant: Samsung Display Co., Ltd., Yongin-Si (KR)

(72) Inventors: Jeongkuk Kim, Yongin-si (KR); Youngjin Song, Yongin-si (KR); Jinwoo Lee, Yongin-si (KR); Sugwoo Jung, Yongin-si (KR); Sungwon Cho, Yongin-si (KR); Junho Jo, Yongin-si (KR)

(21) Appl. No.: 18/440,424

(22) Filed: Feb. 13, 2024

(30) Foreign Application Priority Data
Jul. 19, 2023 (KR) 10-2023-0093952

(51) Int. Cl. C23C 14/04; H10K 71/16

(52) U.S. Cl. CPC C23C 14/042; H10K 71/166

(57) ABSTRACT

An apparatus for manufacturing a display apparatus includes a mask assembly, wherein the mask assembly includes a first mask layer including a silicon material, a first portion, and a second portion on the first portion, wherein a first portion opening is disposed in the first portion and a plurality of second portion openings are disposed in the second portion above the first portion opening, and a second mask layer disposed on the first mask layer. The second mask layer includes an inorganic material, wherein the inorganic material has a plurality of second mask openings above the plurality of second portion openings, and wherein, in a cross-sectional view, a width of each of the plurality of second portion openings increases with distance from the second mask layer.

### CROSS-REFERENCE TO RELATED APPLICATIONS

This application is based on and claims priority, under 35 U.S.C. § 119, to Korean Patent Application No. 10-2023-0093952 filed on Jul. 19, 2023 in the Korean Intellectual Property Office, the disclosure of which is incorporated by reference herein in its entirety.

### BACKGROUND

### 1. Field

One or more embodiments relate to an apparatus and a method, and more particularly, to an apparatus for manufacturing a display apparatus, a method of manufacturing a display apparatus, and a mask assembly.

### 2. Description of the Related Art

Mobile electronic apparatuses are widely used. Specifically, small and portable electronic apparatuses such as mobile phones, tablet personal computers (PCs) are widely used as mobile electronic apparatuses.

To support various functions, such as to provide a user with visual information, the mobile electronic apparatuses include a display apparatus. Recently, as parts that drive a display apparatus have been miniaturized, the portion of an electronic apparatus that is taken up by the display apparatus has gradually increased. The display device taking up a larger portion of an electronic device motivated the development of a display structure that allows the display to be bent to a preset angle from a flat state.

### SUMMARY

One or more embodiments include an apparatus for manufacturing a display apparatus including a mask assembly with a simplified manufacturing process and improved durability.

However, the disclosure is not limited thereto.

Additional aspects will be set forth in the description that follows and, in part, will be apparent from the description, or may be learned by practice of the presented embodiments of the disclosure.

According to one or more embodiments, an apparatus for manufacturing a display apparatus includes a chamber, a mask assembly disposed inside the chamber to face a display substrate, and a deposition source disposed inside the chamber to face the mask assembly and configured to supply a deposition material such that the deposition material passes through the mask assembly and is deposited on the display substrate, wherein the mask assembly includes a first mask layer including a silicon material, a first portion, and a second portion on the first portion, wherein a first portion opening is disposed in the first portion, and a plurality of second portion openings are disposed in the second portion above the first portion opening, and a second mask layer disposed on the first mask layer and including an inorganic material, the inorganic material having a plurality of second mask openings above the plurality of second portion openings, and wherein, in a cross-sectional view, a width of each of the plurality of second portion openings increases with distance from the second mask layer.

In a plan view, boundaries of at least two of the plurality of second portion openings may be in contact with each other.

At least two of the plurality of second portion openings may be spaced apart from each other.

The plurality of second portions may be tapered.

A width of each of the plurality of second portions may be between 0 μm and 14 μm, inclusive, at any point along its length.

In a cross-sectional view, a slope angle of a lateral surface of the plurality of second portion openings may be greater than 0° and less than or equal to 85° with respect to a plane that is parallel to a top surface of the mask.

The first portion and the second portion may be integrated.

According to one or more embodiments, a mask assembly includes a first mask layer including a silicon material, a first portion, and a second portion on the first portion, wherein a first portion opening is disposed in the first portion, and a plurality of second portion openings are disposed in the second portion above the first portion opening, and a second mask layer disposed on the first mask layer and including an inorganic material, the inorganic material having a plurality of second mask openings above the plurality of second portion openings, and wherein, in a cross-sectional view, a width of each of the plurality of second portion openings may increase with distance from the second mask layer.

In a plan view, boundaries of at least two of the plurality of second portion openings may be in contact with each other.

At least two of the plurality of second portion openings may be spaced apart from each other.

The plurality of second portion openings may be tapered.

A width of each of the plurality of second portion may be between 0 μm and 14 μm, inclusive, at any point along its length.

In a cross-sectional view, a slope angle of a lateral surface of the plurality of second portion openings may be greater than 0° and less than or equal to 85° with respect to a plane that is parallel to a top surface of the mask.

The first portion and the second portion may be integrated.

According to one or more embodiments, a method of manufacturing a display apparatus includes disposing a display substrate in a chamber, disposing a mask assembly in the chamber, and supplying, from a deposition source, a deposition material toward the mask assembly, wherein the disposing of the mask assembly includes disposing a second mask layer on a first mask layer, patterning the second mask layer such that a plurality of second mask openings are disposed in the second mask layer, forming a plurality of second portion openings in the first mask layer by etching the first mask layer through the plurality of second mask openings, and forming an opening in a lower portion of the first mask layer.

In the etching of the portion of the first mask layer, a first space may be formed in a lower portion of the plurality of second portion openings, and the first space may be connected to the plurality of second portion openings.

When a portion of the first mask layer is etched, a plurality of first openings formed in the first mask layer may be spatially separated from each other.

The forming of the opening in the lower portion of the first mask layer may include disposing a protective layer such that at least a portion of the protective layer is received in the plurality of second portion openings and the plurality of second mask openings, etching a lower portion of the first mask layer to expose a lower portion of the protective layer, and removing the protective layer.

The disposing of the protective layer may include disposing a portion of the protective layer in a first space formed in a lower portion of the plurality of second portion openings.

The etching of the lower portion of the first mask layer to expose the lower portion of the protective layer may include exposing a portion of the first mask layer sealed by the protective layer by removing the protective layer.

These and/or other aspects will become apparent and more readily appreciated from the following detailed description of the embodiments, the accompanying drawings, and claims.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of an apparatus for manufacturing a display apparatus, according to an embodiment;

FIG. 2 is a schematic cross-sectional view of a mask assembly according to an embodiment;

FIG. 3 is a schematic plan view of a portion of a second mask assembly according to an embodiment;

FIGS. 4 through 9 are schematic cross-sectional views of a mask assembly according to an embodiment;

FIG. 10 is a schematic perspective view of a display apparatus according to an embodiment;

FIG. 11 is a schematic cross-sectional view of a display apparatus according to an embodiment;

FIG. 12 is a schematic plan view of the display panel according to an embodiment;

FIG. 13 is an equivalent circuit diagram of a pixel of a display apparatus according to an embodiment;

FIG. 14 is a schematic cross-sectional view of a mask assembly according to an embodiment;

FIG. 15 is a schematic plan view of a portion of a second mask layer according to an embodiment; and

FIGS. 16 through 21 are schematic cross-sectional views of a mask assembly according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the written description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements are not limited to any order by the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the disclosure is not necessarily limited thereto.

The x-axis, the y-axis and the z-axis are not limited to three orthogonal axes of the rectangular coordinate system, and may be interpreted in a broader sense. For example, the x-axis, the y-axis, and the z-axis may be perpendicular to one another, or may represent different orientations that are not perpendicular to one another.

In the case where a certain embodiment may be implemented differently, a specific process order may be performed in the order different from the order in which the process steps are described. For example, two processes successively described may be performed simultaneously or performed in the reverse order.

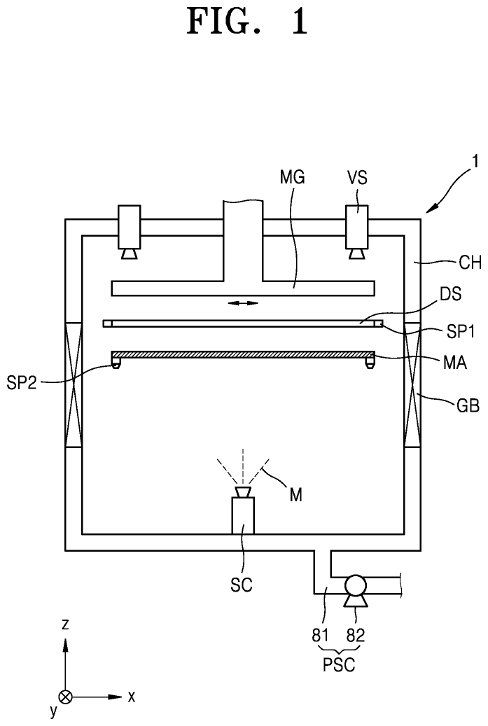

FIG. 1 is a schematic cross-sectional view of an apparatus 1 for manufacturing a display apparatus, according to an embodiment.

The apparatus 1 for manufacturing a display apparatus may include a chamber CH, a first supporter SP1, a second supporter SP2, a mask assembly MA, a deposition source SC, a magnetic force portion MG, a vision portion VS, and a pressure adjustor PSC.

A space may be formed inside the chamber CH. A display substrate DS and the mask assembly MA may be received in the space. In this case, a portion of the chamber CH may be open, and a gate valve GB may be installed in the open portion of the chamber CH. In this case, the open portion of the chamber CH may be opened or closed according to an operation of the gate valve GB.

In this case, the display substrate DS may denote the display substrate DS in which at least one of an organic layer, an inorganic layer, and a metal layer is deposited on a substrate 100 described below while the display apparatus is manufactured. Alternatively, the display substrate DS may be the substrate 100 on which any of the organic layer, the inorganic layer, and the metal layer is not yet deposited.

The first supporter SP1 may be configured to support the display substrate DS. In this case, the first supporter SP1 may be a plate form fixed inside the chamber CH. In another embodiment, the first supporter SP1 may be a shuttle form in which the display substrate DS is seated and which is linearly movable inside the chamber CH. In another embodiment, the first supporter SP1 may include an electrostatic chuck or an adhesive chuck disposed in the chamber CH to be fixed or movable inside the chamber CH.

The second supporter SP2 may be configured to support the mask assembly MA. In this case, the second supporter SP2 may be disposed inside the chamber CH. The second supporter SP2 may fine-adjust the position of the mask assembly MA. In this case, the second supporter SP2 may include a driver, an alignment unit, or the like separately to move the mask assembly MA in different directions.

In another embodiment, the second supporter SP2 may be a shuttle form. In this case, the mask assembly MA may be seated on the second supporter SP2. The second supporter SP2 may be configured to transfer the mask assembly MA. For example, the second supporter SP2 may move to the outside of the chamber CH, and after the mask assembly MA is seated on the second supporter SP2, and then the second supporter SP2 may enter the chamber CH from the outside of the chamber CH.

In this case, the first supporter SP1 may be integrally formed with the second supporter SP2. In this case, the first supporter SP1 and the second supporter SP2 may include a movable shuttle. In this case, the first supporter SP1 and the second supporter SP2 may include a structure configured to fix the mask assembly MA to the display substrate DS with the display substrate DS seated on the mask assembly MA and be configured to linearly move the display substrate DS and the mask assembly MS simultaneously.

Hereinafter, for convenience of description, the form in which the first supporter SP1 and the second supporter SP2 are formed to be discriminated from each other and arranged in different positions, and the form in which the first supporter SP1 and the second supporter SP2 are disposed inside the chamber CH, are mainly described in detail.

The mask assembly MA may be disposed to face the display substrate DS inside the chamber CH. A deposition material M may pass through the mask assembly MA and be deposited on the display substrate DA.

The deposition source SC may be disposed to face the mask assembly MA and configured to supply the deposition material M such that the deposition material M passes through the mask assembly MA and is deposited on the display substrate DS. In this case, the deposition source SC may evaporate or sublimate the deposition material M by applying heat to the deposition material M. The deposition source SC may be disposed to be fixed inside the chamber CH, or disposed inside the chamber CH to be linearly movable in one direction.

The magnetic force portion MG may be disposed inside the chamber CH to face the display substrate DS and/or the mask assembly MA. In this case, the magnetic force portion MG may apply magnetic force to the mask assembly MA and attract the mask assembly MA toward the display substrate DS.

The vision portion VS may be disposed in the chamber CH and may capture the positions of the display substrate DS and the mask assembly MA. In this case, the vision portion VS may include a camera configured to capture the display substrate DS and the mask assembly MA. The positions of the display substrate DS and the mask assembly MA may be determined based on the images captured by the vision portion VS, and the transformation of the mask assembly MA may be determined. In addition, the first supporter SP1 may be configured to fine-adjust the position of the display substrate DS, or the second supporter SP2 may be configured to fine-adjust the position of the mask assembly MA based on the captured images. Hereinafter, the case where the second supporter SP2 is configured to fine-adjust the position of the mask assembly MA and align the positions of the display substrate DS and the mask assembly MA, is mainly described in detail.

The pressure adjustor PSC may be connected to the chamber CH and configured to adjust the inner pressure of the chamber CH. As an example, the pressure adjustor PSC may be configured to adjust the inner pressure of the chamber CH to be equal or similar to the atmospheric pressure. In addition, the pressure adjustor PSC may be configured to adjust the inner pressure of the chamber CH to be equal or similar to a vacuum state.

The pressure adjustor PSC may include a connection pipe 81 and a pump 82, wherein the connection pipe 81 is connected to the chamber 10, and the pump 82 is installed to the connection pipe 81. In this case, external air may be introduced through the connection pipe 81 or a gas inside the chamber CH may be guided to the outside through the connection pipe 81 according to an operation of the pump 82.

A method of manufacturing the display apparatus (not shown) by using the apparatus 1 for manufacturing a display apparatus, is described. First, the display substrate DS may be prepared.

The pressure adjustor PSC may maintain the inside of the chamber CH at a state equal or similar to the atmospheric pressure. The gate valve GB may operate to open the open portion of the chamber CH.

Then, the display substrate DS may be loaded into the inside of the chamber CH from the outside. In this case, the display substrate DS may be loaded into the chamber CH using various methods. As an example, the display substrate DS may be loaded into the inside of the chamber CH from the outside of the chamber CH by a robot arm arranged outside the chamber CH. In another embodiment, in the case where the first supporter SP1 is formed in a shuttle form, the first supporter SP1 may be carried from the inside of the chamber CH to the outside of the chamber CH, then, the display substrate DS may be seated on the first supporter SP1 by a sperate robot arm arranged outside the chamber CH, and the first supporter SP1 may be loaded into the inside of the chamber CH from the outside of the chamber CH.

The mask assembly MA may be arranged inside the chamber CH as described above. In another embodiment, in the same or similar manner to the display substrate DS, the mask assembly MA may be loaded into the inside of the chamber CH from outside of the chamber CH.

When the display substrate DS is loaded into the inside of the chamber CH, the display substrate DS may be seated on the first supporter SP1. In this case, the vision portion VS may be configured to capture the positions of the display substrate DS and the mask assembly MA. The positions of the display substrate DS and the mask assembly MA may be determined based on images captured by the vision portion VS. In this case, the apparatus 1 for manufacturing a display apparatus may include a separate controller (not shown) to determine the positions of the display substrate DS and the mask assembly MA.

When the determination of the positions of the display substrate DS and the mask assembly MA is completed, the second supporter SP2 may fine-adjust the position of the mask assembly MA.

Then, the deposition source SC operates to supply the deposition material M toward the mask assembly MA, and the deposition material M passing through the mask assembly MA may be deposited on the display substrate DS. In this case, the deposition source SC may move in parallel to the display substrate DS and the mask assembly MA, or the display substrate DS and the mask assembly MA may move in parallel to the deposition source SC. That is, the deposition source SC may move relative to the display substrate DS and the mask assembly MA. In this case, the pump 82 may maintain the pressure of the chamber CH at a state equal or similar to vacuum by sucking in the gas inside the chamber CH and discharging the gas to the outside.

As described above, the deposition material M supplied from the deposition source SC may pass through the mask assembly MA, be deposited on the display substrate DS, and thus, may form at least one of a plurality of layers, for example, an organic layer, an inorganic layer, and a metal layer stacked in the display apparatus described below.

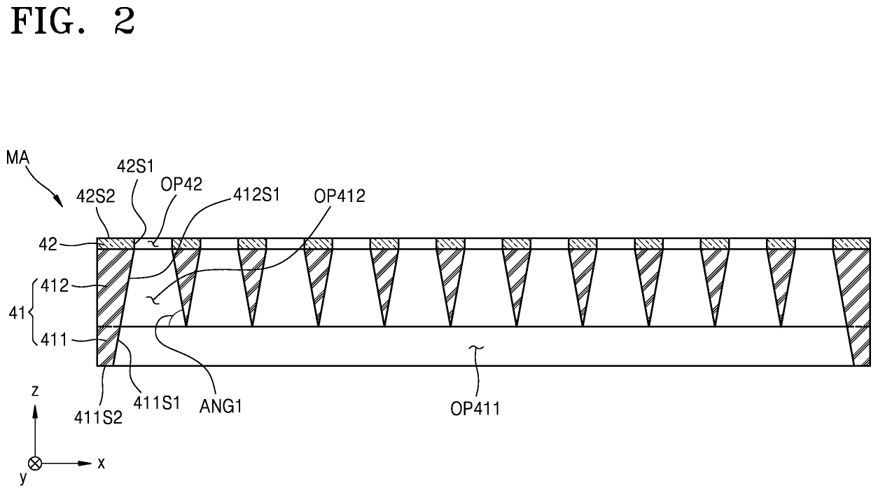

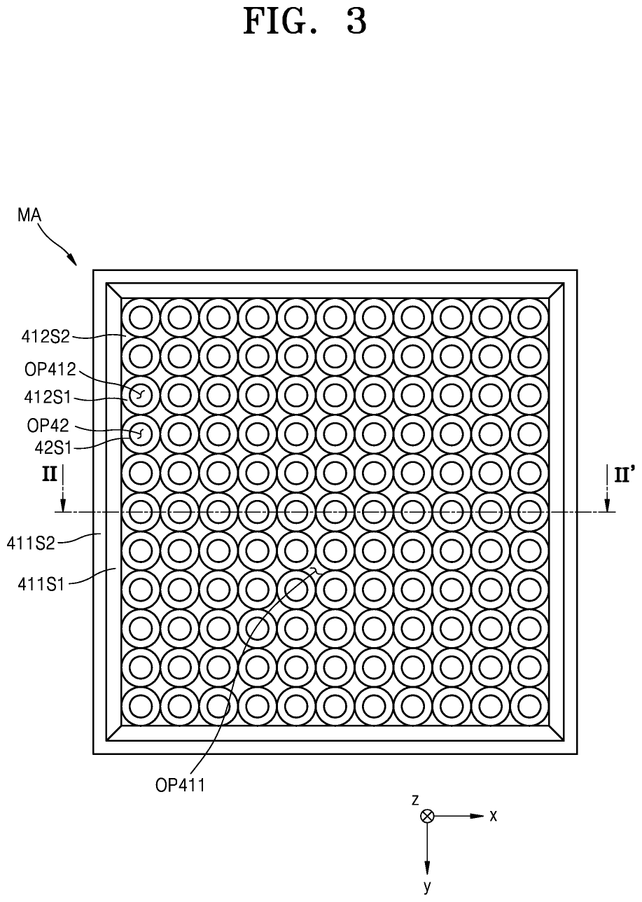

FIG. 2 is a schematic cross-sectional view of the mask assembly MA according to an embodiment, and FIG. 3 is a schematic plan view of a portion of a second mask layer 42 according to an embodiment. Specifically, FIG. 2 may correspond to a cross-section of the mask assembly, taken along line II-II′ of FIG. 3.

Referring to FIGS. 2 and 3, the mask assembly MA may include a first mask layer 41 and the second mask layer 42.

The first mask layer 41 may include a silicon material. As an example, the first mask layer 41 may include at least one of silicon oxide (SiOₓ), silicon nitride (SiNₓ), and silicon oxynitride (SiOₓNy).

The first mask layer 41 may include a first portion 411 and a second portion 412. The first portion 411 and the second portion 412 may be integrally provided. That is, the first portion 411 and the second portion 412 may include the same material.

The first portion 411 may support the second portion 412 in the lower portion of the second portion 412, and a first portion opening OP411 may be disposed in the first portion. The first portion opening OP411 may be disposed in the center of the first portion 411. The first portion 411 may be provided in a doughnut shape surrounding the periphery of the first portion opening OP411. For example, one first portion opening OP411 may be provided. The inner peripheral surface of the first portion 411 forming the first portion opening OP411 is referred to as a 1-1 surface 411S1, and the lower surface of the first portion 411 is referred to as a 1-2 surface 411S2. The 1-2 surface 411S2 may be parallel to the upper surface of the mask assembly MA and inclined with respect to the 1-1 surface 411S1.

The second portion 412 may be disposed on the first portion 411, and a plurality of second portion openings OP412 may be disposed in the second portion 412. The plurality of second portion openings OP412 may overlap the first portion opening OP411. For example, the plurality of second portion openings OP412 may overlap one first portion opening OP411. The inner peripheral surface of the second portion 412 forming the plurality of second portion openings OP412 is referred to as a 2-1 surface 412S1.

The 2-1 surface 412S1 may be inclined with respect to the upper surface of the mask assembly MA. That is, in a cross-sectional view, the lateral surface of the plurality of second portion openings OP412 may be inclined with respect to the upper surface of the mask assembly MA. In a cross-sectional view, the width of each of the plurality of second portion openings OP412 may gradually increase away from the second mask layer 42 described below. That is, in a cross-sectional view, the first portion 411 and the second portion 412 may be tapered, getting thinner with distance from the second mask layer 42. In this structure, a phenomenon that at least a portion of the deposition material M (see FIG. 1) is blocked by the second portion 412 and does not pass through the second portion opening OP412, that is, a shadow phenomenon may be reduced.

In a cross-sectional view, a slope angle of the lateral surface of the plurality of second portion openings OP412 is referred to as a first angle ANG1. For example, the first angle ANG1 may be between 0° and 85°, inclusive, with respect to a plane that is parallel to an upper surface of the mask MA. In addition, the width (in the x-direction) of the second portion 412 at any point along the z-direction may be between 0 μm and 14 μm, inclusive, as it tapers. As shown in FIG. 3, in a plan view, boundaries of at least two of the plurality of second portion openings OP412 may be in contact with each other.

The second mask layer 42 may be disposed on the first mask layer 41. The second mask layer 42 may include an inorganic material. As an example, the second mask layer 42 may include at least one of silicon oxide (SiOₓ), silicon nitride (SiNₓ), and silicon oxynitride (SiOₓNy).

A plurality of second mask openings OP42 may be disposed in the second mask layer 42. The plurality of second mask openings OP42 may be placed above the plurality of second portion openings OP412. The deposition material M (see FIG. 1) may sequentially pass through the first portion opening OP411, the plurality of second portion openings OP412, and the plurality of second mask openings OP42. Because the second portion 412 supports the second mask layer 42, transformation of the second mask layer 42 is reduced and durability of the second mask layer 42 may be improved.

In a cross-sectional view, the width of the plurality of second portion openings OP412 that are in contact with the second mask layer 42 may be equal to the width of the plurality of second mask openings OP42. The inner peripheral surface of the second mask layer 42 forming the plurality of second mask openings OP42 is referred to as a 3-1 surface 42S1, and the upper surface of the second mask layer 42 is referred to as a 3-2 surface 42S2. The 2-1 surface 412S1 and the 3-1 surface 42S1 may be in contact with each other. An angle between the 3-1 surface 42S1 and the 3-2 surface 42S2 may be about 90°.

In a plan view, although it is shown in FIG. 3 that the shapes of the first mask layer 41, the second mask layer 42, and the first portion opening OP411 are quadrangles, and the shapes of the plurality of second portion openings OP412 and the plurality of second mask openings OP42 are circles, this is just an example, and the shape of the mask assembly MA is not limited thereto.

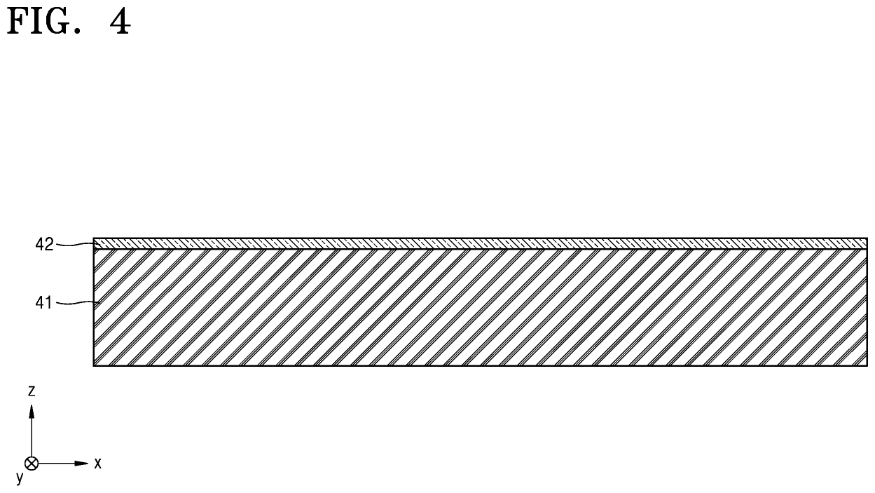

FIGS. 4 to 9 are schematic cross-sectional views of the mask assembly MA according to an embodiment.

In FIGS. 4 to 9, the same reference numerals as those of FIGS. 1 to 3 denote the same members, and thus, repeated descriptions thereof are omitted.

First, referring to FIG. 1, a method of manufacturing a display apparatus may include disposing the display substrate DS (see FIG. 1) inside the chamber CH (see FIG. 1), disposing the mask assembly MA inside the chamber CH (see FIG. 1), and supplying, from the deposition source SC (see FIG. 1), the deposition material M (see FIG. 1) toward the mask assembly MA.

Referring to FIGS. 4 to 9, an operation of disposing the mask assembly MA inside the chamber CH (see FIG. 1) is known.

Referring to FIG. 4, the disposing of the mask assembly MA may include disposing the second mask layer 42 on the first mask layer 41. In this case, the upper surface of the first mask layer 41 and the lower surface of the second mask layer 42 may be in contact with each other. The first mask layer 41 and the second mask layer 42 may be fixed to each other.

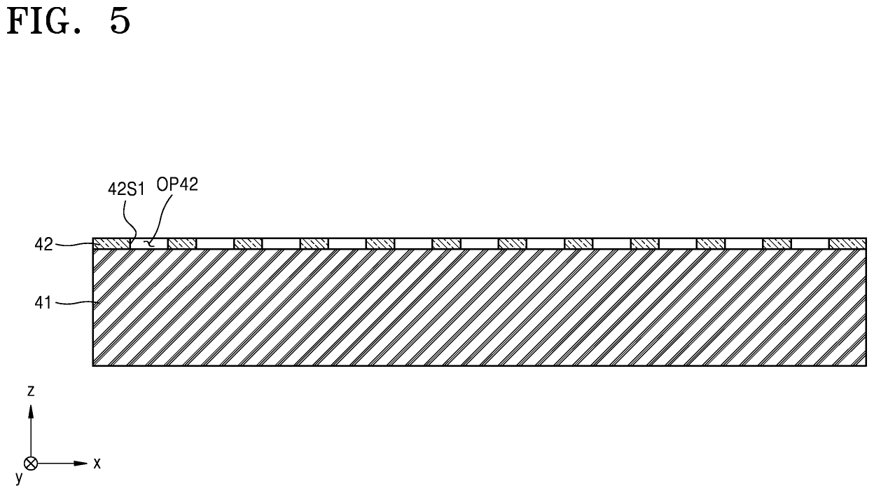

Referring to FIG. 5, the disposing of the mask assembly MA may include patterning the second mask layer 42 such that the plurality of second mask openings OP42 are disposed in the second mask layer 42.

While the second mask layer 42 is patterned, the 3-1 surface 42S1 may be formed. A portion of the upper surface of the first mask layer 41 may be exposed from the second mask layer 42 by the plurality of second mask openings OP42. As an example, the patterning of the second mask layer 42 may be performed by dry etching through a photolithography process. However, this is just an example, and the patterning of the second mask layer 42 is not limited thereto.

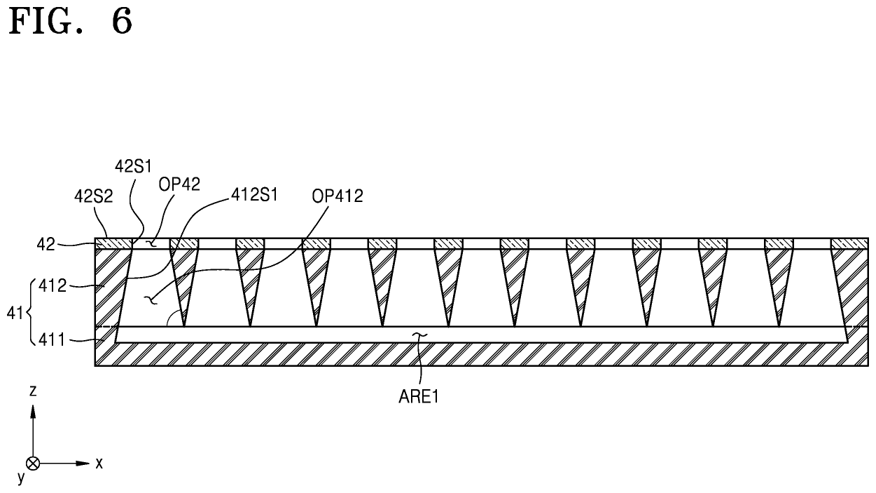

Referring to FIG. 6, the disposing of the mask assembly MA may include etching a portion of the first mask layer 41 overlapping the plurality of second mask openings OP42 to form the plurality of second portion openings OP412 in the first mask layer 41.

In the etching of the portion of the first mask layer 41, a first space ARE1 may be formed under the plurality of second portion openings OP412. The first area ARE1 and the plurality of second portion openings OP412 may communicate with each other. The first mask layer 41 may be divided into the first portion 411 and the second portion 412 based on the first space ARE1. A portion of the first mask layer 41 disposed under the upper surface of the first space ARE1 is referred to as the first portion 411, and a portion of the first mask layer 41 disposed on the upper surface of the first space ARE1 is referred to as the second portion 412.

As an example, a portion of the first mask layer 41 may be dry-etched by an etching gas. In the etching of a portion of the first mask layer 41, the second mask layer 42 may serve as a mask with respect to the etching gas. That is, the etching gas may pass through the plurality of second mask openings OP42 but not pass through the 3-2 surface 42S2 with the 3-1 surface 42S1 as a boundary. Accordingly, a portion of the first mask layer 41 overlapping the plurality of second mask openings OP42 may be etched and the plurality of second portion openings OP412 and the first space ARE1 may be formed. During this process, because a separate photoresist process is not required, the process is simplified, the time required may be shortened, and the manufacturing cost may be reduced.

In this case, in a cross-sectional view, the width of each of the plurality of second portion openings OP412 may gradually increase away from the second mask layer 42. However, this is just an example, and a portion of the first mask layer 41 may be wet-etched by an etching solution.

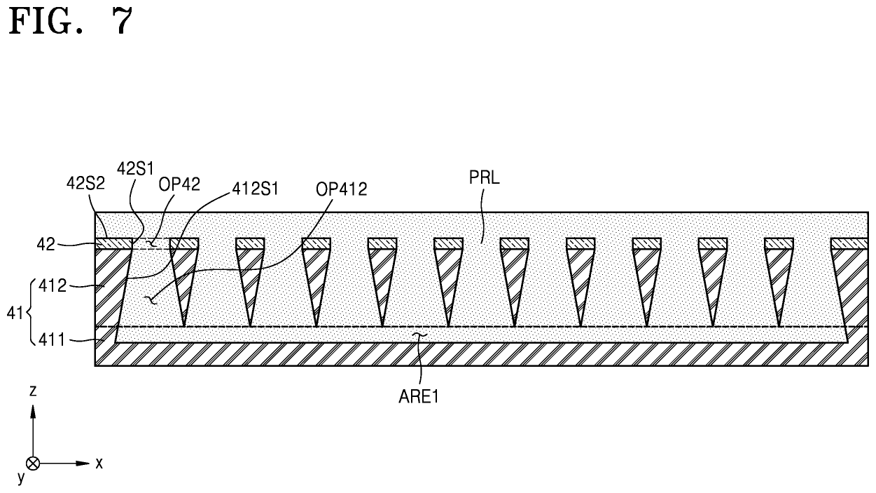

Referring to FIGS. 7 to 9, the disposing of the mask assembly MA may include forming an opening in the lower portion of the first mask layer 41.

First, referring to FIG. 7, the forming of the opening in the lower portion of the first mask layer 41 may include disposing a protective layer PRL such that at least a portion of the protective layer PRL is received in the plurality of second portion openings OP412 and the plurality of second mask openings OP42. Here, the protective layer PRL may include a photoresist material.

In the disposing of the protective layer PRL, a portion of the protective layer PRL may be disposed in the first space ARE1 formed under the plurality of second portion openings OP412. In addition, a portion of the protective layer PRL may be disposed on the second mask layer 42. The protective layer PRL may be in contact with the first portion 411, the second portion 412, and the second mask layer 42. Particularly, the 2-1 surface 412S1, the 3-1 surface 42S1, and the 3-2 surface 42S2 may be sealed from the outside by the protective layer PRL.

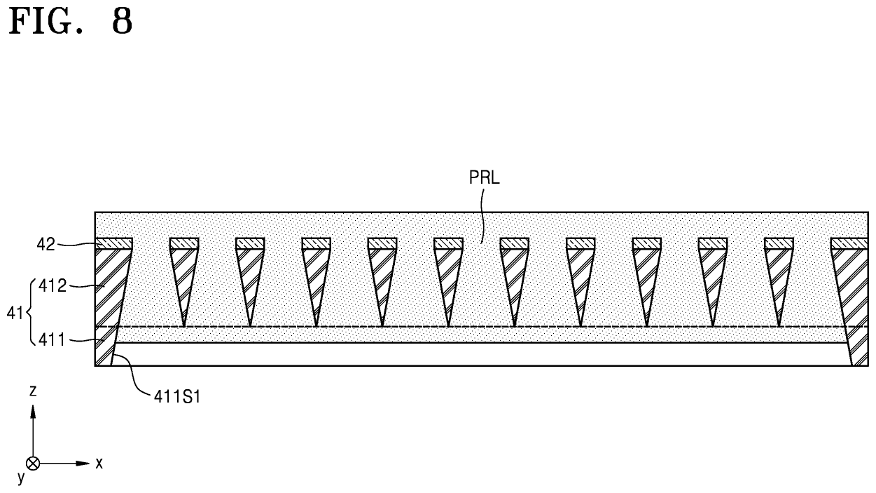

Referring to FIG. 8, the forming of the opening in the lower portion of the first mask layer 41 may include etching the lower portion of the first mask layer 41 to expose the lower surface of the protective layer PRL to the outside from the first mask layer 41.

As an example, the lower portion of the first mask layer 41 may be dry-etched by an etching gas. Because the opening is formed in the lower portion of the first mask layer 41, the first portion 411 is exposed to the outside, and the second portion 412 may be in contact with the protective layer PRL. In addition, the 1-1 surface 411S1 may be formed in the first portion 411. In this case, because the second portion 412 and the second mask layer 42 surrounded by the protective layer PRL are protected by the protective layer PRL, the second portion 412 and the second mask layer 42 may not be etched. However, this is just an example, and the lower portion of the first mask layer 41 may be wet-etched by an etching solution.

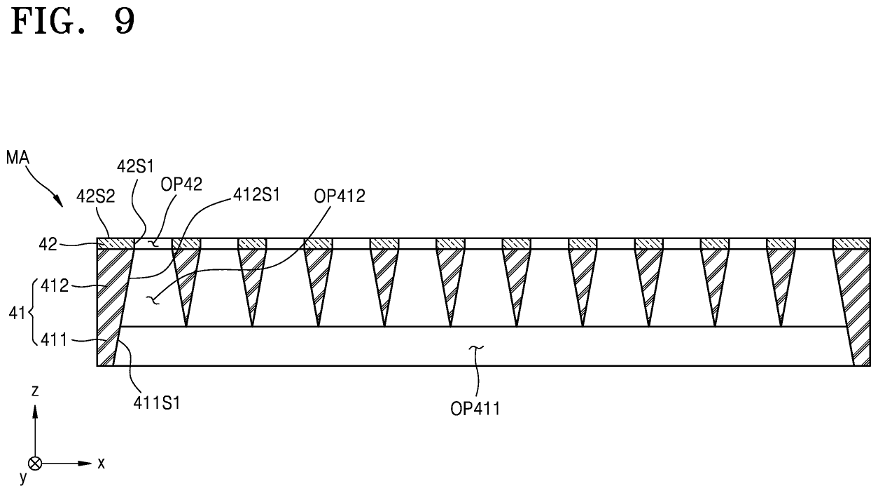

Referring to FIG. 9, the forming of the opening in the lower portion of the first mask layer 41 may include removing the protective layer PRL.

The protective layer PRL may be removed from the first portion opening OP411, the plurality of second portion openings OP412, and the plurality of second mask openings OP42. The protective layer PRL may be removed by developing the protective layer PRL containing a photoresist material. Accordingly, the outer surfaces of the first portion 411, the second portion 412, and the second mask layer 42 may be exposed to the outside. That is, the 1-1 surface 411S1, the 2-1 surface 412S1, the 3-1 surface 42S1, and the 3-2 surface 42S2 may be exposed to the outside.

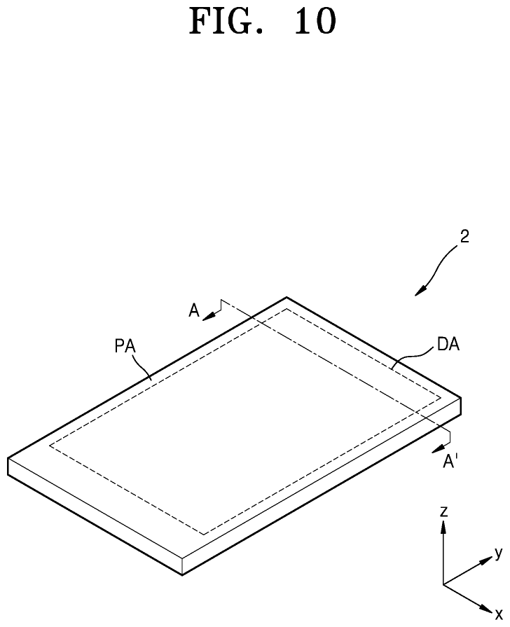

FIG. 10 is a schematic perspective view of a display apparatus 2 according to an embodiment.

Referring to FIG. 10, the display apparatus 2 includes a display area DA and a peripheral area PA surrounding the display area DA. The display apparatus 2 may be configured to display images by using light emitted from a plurality of pixels arranged in the display area DA.

The peripheral area PA may surround the display area DA entirely. The peripheral area PA is a kind of non-display area in which pixels are not arranged and a driver or wirings configured to provide electrical signals or power to the pixels may be arranged.

As shown in FIG. 10, although the display apparatus 2 may have a rectangular shape in which a horizontal length is greater than a vertical length, the embodiment is not limited thereto. The display apparatus 2 may have various shapes such as polygons, circles, ellipses, or the like. Hereinafter, although an organic light-emitting display apparatus is described as an example of the display apparatus 2 according to an embodiment, the display apparatus is not limited thereto. In another embodiment, a display apparatus of another type such as a quantum-dot light-emitting display may be used.

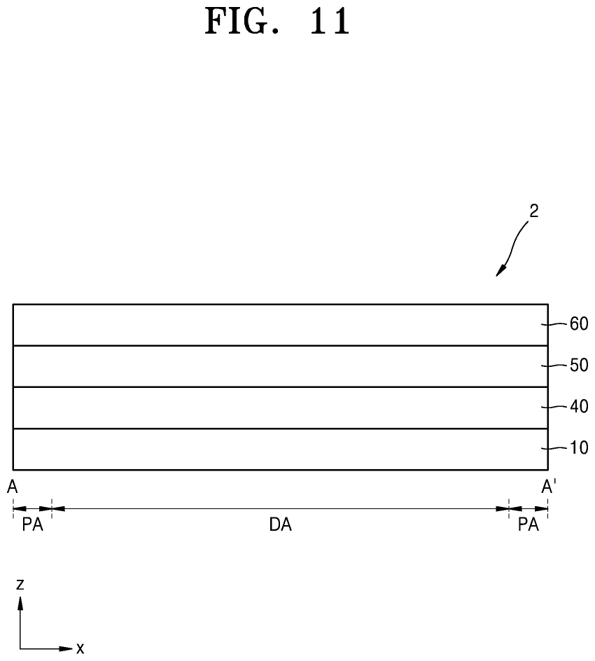

FIG. 11 is a schematic cross-sectional view of a display apparatus according to an embodiment. FIG. 11 may correspond to a line A-A′ of FIG. 10.

Referring to FIG. 11, the display apparatus 2 may include a display panel 10, an input sensing layer 40 disposed on the display panel 10, and an optical functional layer 50. These elements may be covered by a window 60. The display apparatus 2 may be various kinds of electronic apparatuses such as mobile phones, notebook computers, and smartwatches.

The display panel 10 may be configured to display images. The display panel 10 may include pixels arranged in the display area DA. The pixels may each include a display element and a pixel circuit connected thereto. The display element may include an organic light-emitting diode or a quantum-dot organic light-emitting diode, and the like.

The input sensing layer 40 may obtain coordinate information corresponding to an external input, for example, a touch event. The input sensing layer 40 may include a sensing electrode (or a touch electrode) and trace lines connected to the sensing electrode. The input sensing layer 40 may be disposed on the display panel 10. The input sensing layer 40 may sense an external input by using a self-capacitance method and/or a mutual capacitance method.

The input sensing layer 40 may be directly formed on the display panel 10, or separately formed and then coupled to the display panel 10 by an adhesive layer such as a clear adhesive. As an example, the input sensing layer 40 may be successively formed after a process of forming the display panel 10. In this case, the input sensing layer 40 may be a portion of the display panel 10, and an adhesive layer may not be disposed between the input sensing layer 40 and the display panel 10. Although it is shown in FIG. 11 that the input sensing layer 40 is disposed between the display panel 10 and the optical functional layer 50, the input sensing layer 40 may be disposed on the optical functional layer 50.

The optical functional layer 50 may include an anti-reflection layer. The anti-reflection layer may reduce reflectivity of light (external light) incident toward the display panel 10 from outside through the window 60. In an embodiment, the anti-reflection layer may include a black matrix and color filters. The color filters may be arranged by taking into account colors of pieces of light emitted respectively from the pixels of the display panel 10.

In another embodiment, the anti-reflection layer may include a phase retarder and a polarizer. The phase retarder may include a film-type retarder or a liquid crystal-type retarder. The phase retarder may include a λ/2 phase retarder and/or a λ/4 phase retarder. The polarizer may include a film-type polarizer or a liquid crystal-type polarizer. The film-type polarizer may include a stretchable synthetic resin film, and the liquid crystal-type polarizer may include liquid crystals arranged in a predetermined arrangement. Each of the phase retarder and the polarizer may further include a protective film. The phase retarder and the polarizer itself or the protective film may be defined as a base layer of the anti-reflection layer.

In another embodiment, the anti-reflection layer may include a destructive interference structure. The destructive interference structure may include a first reflection layer and a second reflection layer respectively disposed on different layers. First-reflected light and second-reflected light respectively reflected by the first reflection layer and the second reflection layer may destructively interfere and thus the reflectivity of external light may be reduced.

In an embodiment, the optical functional layer 50 may be successively formed after a process of forming the display panel 10 and/or the input sensing layer 40. In this case, an adhesive layer may not be disposed between the optical function layer 50 and the display panel 10 and/or the input sensing layer 40.

Although not shown in FIG. 11, a layer including an optically clear adhesive or an optically clear resin and the like may be disposed between the window 60 and the optical functional layer 50.

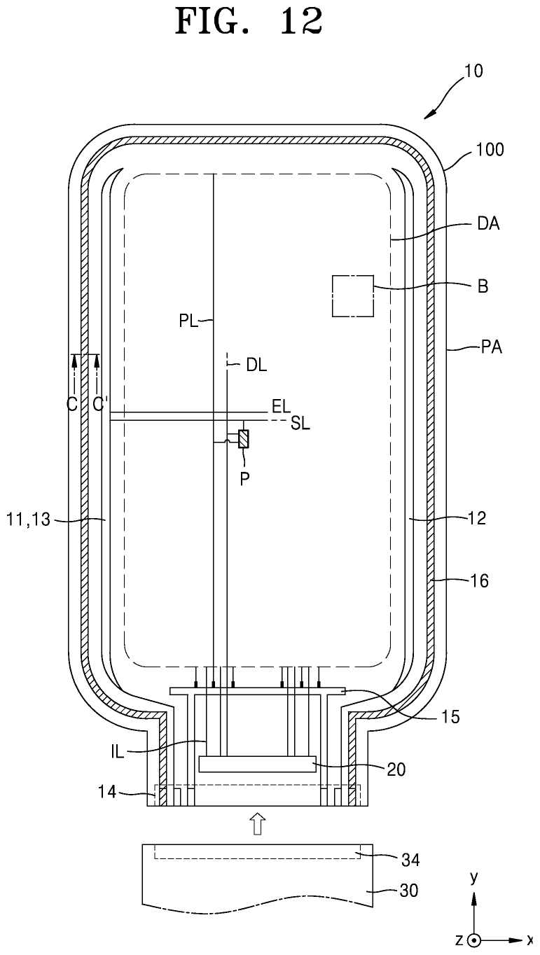

FIG. 12 is a schematic plan view of the display panel according to an embodiment. As described with reference to FIG. 11, the display apparatus according to an embodiment may include the display panel 10. FIG. 12 may be understood as a substrate 100 of the display panel 10.

Referring to FIG. 12, the display panel 10 may include the display area DA and the peripheral area PA outside the display area DA. The display area DA is a portion configured to display images, and a plurality of pixels P may be arranged in the display area DA. The display area DA may have various shapes, for example, circular shapes, elliptical shapes, polygonal shapes, or shapes of specific figures. It is shown in FIG. 12 that the display area DA has an approximately rectangular shape having round corners.

Each of the pixels P may denote a sub-pixel and include a display element such as an organic light-emitting diode OLED. The pixel P may be configured to emit, for example, red, green, blue, or white light.

The peripheral area PA may be arranged outside the display area DA. Outer circuits may be arranged in the peripheral area PA, wherein the outer circuits are configured to drive the pixels P. A first scan driving circuit 11, a second scan driving circuit 12, an emission control driving circuit 13, a terminal 14, a driving power supply line 15, and a common power supply line 16 may be arranged in the peripheral area PA.

The first scan driving circuit 11 may be configured to provide scan signals to the pixel P through a scan line SL. The second scan driving circuit 12 may be arranged in parallel to the first scan driving circuit 11 with the display area DA therebetween. Some of the pixels P arranged in the display area DA may be electrically connected to the first scan driving circuit 11, and the others may be connected to the second scan driving circuit 12. When needed, the second scan driving circuit 12 may be omitted, and all of the pixels P arranged in the display area DA may be electrically connected to the first scan driving circuit 11.

The emission control driving circuit 13 may be arranged on the side of the first scan driving circuit 11 and configured to provide emission control signals to the pixels P through an emission control line EL. Although it is shown in FIG. 10 that the emission control driving circuit 13 is arranged on only one side of the display area DA, like the first scan driving circuit 11 and the second scan driving circuit 12, the emission control driving circuit 13 may be arranged on two opposite sides of the display area DA.

In an embodiment, the peripheral area PA may include a bending area extending to one side (a-y direction) of the display area DA. The bending area may be bent toward the rear surface of the display area DA to reduce the area of the non-display area when viewed from the front surface of the display apparatus.

A driving chip 20 may be arranged in the peripheral area PA. The driving chip 20 may include an integrated circuit configured to drive the display panel 10. Although the integrated circuit may be a data driving integrated circuit configured to generate data signals, the embodiment is not limited thereto.

The terminal 14 may be arranged in the peripheral area PA. The terminal 14 may be exposed by not being covered by an insulating layer, and electrically connected to a printed circuit board 30. A terminal 34 of the printed circuit board 30 may be electrically connected to the terminal 14 of the display panel 10.

The printed circuit board 30 is configured to transfer signals of a controller (not shown) or power to the display panel 10. Control signals generated by the controller may be respectively transferred to the driving circuits through the printed circuit board 30. In addition, the controller may be configured to transfer a driving voltage ELVDD to the driving power supply line 15 and transfer a common voltage ELVSS to the common power supply line 16. The driving voltage ELVDD may be transferred to each pixel P through a driving voltage line PL connected to the driving power supply line 15, and the common voltage ELVSS may be transferred to an opposite electrode of the pixel P connected to the common power supply line 16. The driving power supply line 15 may have a shape extending in one direction (the x axis direction) below the display area DA. The common power supply line 16 may have a loop shape having one open side and have a shape partially surrounding the display area DA.

The controller is configured to generate data signals, and the generated data signals are transferred to an input line IL through the driving chip 20 and transferred to the pixel P through a data line DL connected to the input line IL. For reference, a “line” may mean a “wiring”. This is applicable to embodiments below and modifications thereof.

The display substrate DS described with reference to FIGS. 1 to 9 may include the display panel 10 of FIG. 11. Specifically, the display substrate DS described with reference to FIGS. 1 to 9 may include the substrate 100 of FIG. 11.

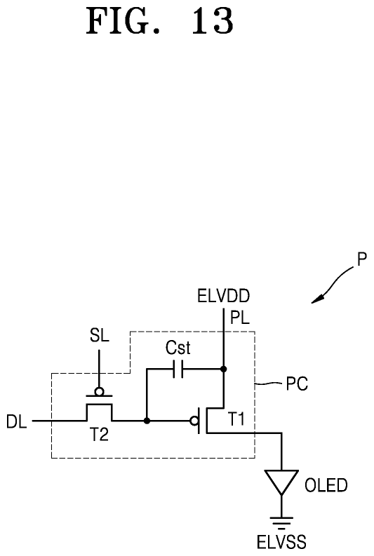

FIG. 13 is an equivalent circuit diagram of a pixel of a display apparatus according to an embodiment.

Referring to FIG. 13, one pixel P may include a pixel circuit PC and an organic light-emitting diode OLED as a display element connected to the pixel circuit PC. The pixel circuit PC may include a first thin-film transistor T1, a second thin-film transistor T2, and a storage capacitor Cst. Each pixel P may emit, for example, red, green, or blue light, or emit red, green, blue, or white light by using the organic light-emitting diode OLED.

The second thin-film transistor T2 is a switching thin-film transistor, may be connected to a scan line SL and a data line DL, and configured to transfer a data voltage to the first thin-film transistor T1 based on a switching voltage, the data voltage being input from the data line DL, and the switching voltage being input from the scan line SL. The storage capacitor Cst may be connected to the second thin-film transistor T2 and a driving voltage line PL and configured to store a voltage corresponding to a difference between a voltage transferred from the second thin-film transistor T2 and the driving voltage ELVDD supplied to the driving voltage line PL.

The first thin-film transistor T1 is a driving thin-film transistor, may be connected to the driving voltage line PL and the storage capacitor Cst, and configured to control a driving current according to the voltage stored in the storage capacitor Cst, the driving current flowing from the driving voltage line PL to the organic light-emitting diode OLED. The organic light-emitting diode OLED may be configured to emit light having a preset brightness corresponding to the driving current. The opposite electrode (e.g., a cathode) of the organic light-emitting diode OLED may be configured to receive the common voltage ELVSS.

Although it is described with reference to FIG. 13 that the pixel circuit PC includes two thin-film transistors and one storage capacitor, the embodiment is not limited thereto. The number of thin-film transistors and the number of storage capacitors may be variously changed according to the design of the pixel circuit PC. As an example, the pixel circuit PC may further include four or more thin-film transistors as well as the two thin-film transistors.

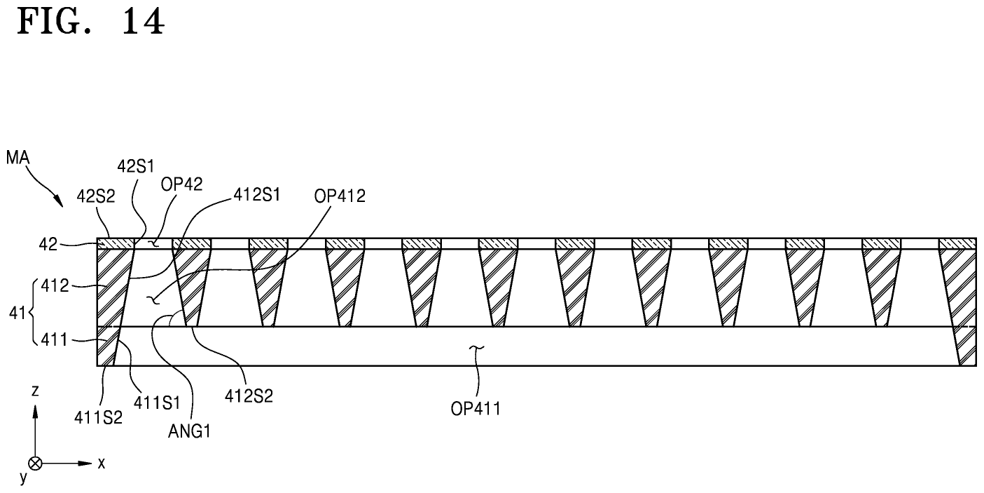

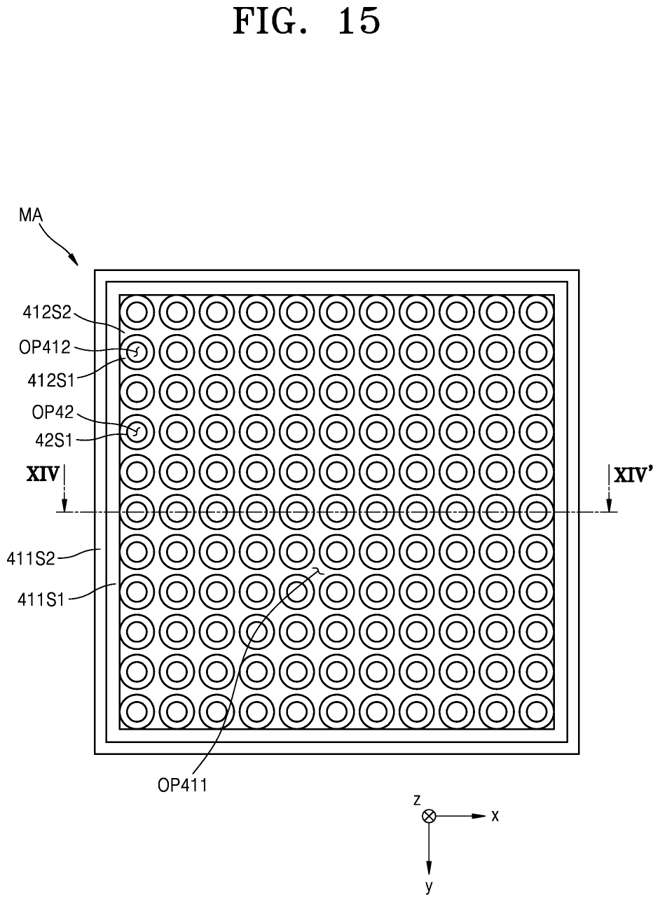

FIG. 14 is a schematic cross-sectional view of the mask assembly MA according to an embodiment, and FIG. 15 is a schematic plan view of a portion of a second mask layer 42 according to an embodiment. Specifically, FIG. 14 may correspond to a cross-section of the second mask layer, taken along line XIV-XIV′ of FIG. 15.

In FIGS. 14 and 15, the same reference numerals as those of FIGS. 2 and 3 denote the same members, and thus, repeated descriptions thereof are omitted.

Referring to FIGS. 14 and 15, the mask assembly MA may include a first mask layer 41 and the second mask layer 42.

The first mask layer 41 may include the first portion 411 and the second portion 412.

The first portion 411 may support the second portion 412 in the lower portion of the second portion 412, and the first portion opening OP411 may be disposed in the first portion. The first portion opening OP411 may be disposed in the center of the first portion 411. The inner peripheral surface of the first portion 411 forming the first portion opening OP411 is referred to as a 1-1 surface 411S1, and the lower surface of the first portion 411 is referred to as a 1-2 surface 411S2. The 1-2 surface 411S2 may be parallel to the upper surface of the mask assembly MA and the 1-1 surface 411S1 may be inclined with respect to the 1-2 surface 411S2.

The second portion 412 may be disposed on the first portion 411, and a plurality of second portion openings OP412 may be disposed in the second portion 412. The plurality of second portion openings OP412 may overlap the first portion opening OP411. The inner peripheral surface of the second portion 412 forming the plurality of second portion openings OP412 is referred to as a 2-1 surface 412S1, and the lower surface of the second portion 412 is referred to as a 2-2 surface 412S2.

The upper surface of the mask assembly MA, the 1-2 surface 411S2, and the 2-2 surface 412S2 may be parallel to one another. The 2-1 surface 412S1 may be inclined with respect to the upper surface of the mask assembly MA. That is, in a cross-sectional view, the lateral surface of the plurality of second portion openings OP412 may be inclined with respect to the upper surface of the mask assembly MA. In a cross-sectional view, the width of each of the plurality of second portion openings OP412 may gradually increase away from the second mask layer 42 described below. That is, in a cross-sectional view, the second portion 412 may be tapered to get narrower with distance from the second mask layer. In this structure, a shadow phenomenon where at least a portion of the deposition material M (see FIG. 1) is blocked by the second portion 412 and does not pass through the second portion opening OP412 may be reduced. As shown in FIG. 15, in a plan view, at least two of the plurality of second portion openings OP412 may be spaced apart from each other.

The second mask layer 42 may be disposed on the first mask layer 41. The plurality of second mask openings OP42 may be disposed in the second mask layer 42. The plurality of second mask openings OP42 may overlap the plurality of second portion openings OP412. The deposition material M (see FIG. 1) may sequentially pass through the first portion opening OP411, the plurality of second portion openings OP412, and the plurality of second mask openings OP42. Because the second portion 412 supports the second mask layer 42, transformation of the second mask layer 42 is reduced and durability of the second mask layer 42 may be improved.

In a cross-sectional view, the width of the plurality of second portion openings OP412 that is in contact with the second mask layer 42 may be equal to the width of the plurality of second mask openings OP42. The inner peripheral surface of the second mask layer 42 forming the plurality of second mask openings OP42 is referred to as a 3-1 surface 42S1, and the upper surface of the second mask layer 42 is referred to as a 3-2 surface 42S2. The 2-1 surface 412S1 and the 3-1 surface 42S1 may be in contact with each other. An angle between the 3-1 surface 42S1 and the 3-2 surface 42S2 may be about 90°.

In a plan view, although it is shown in FIG. 15 that the shapes of the first mask layer 41, the second mask layer 42, and the first portion opening OP411 are quadrangles, and the shapes of the plurality of second portion openings OP412 and the plurality of second mask openings OP42 are circles, this is just an example, and the shape of the mask assembly MA is not limited thereto.

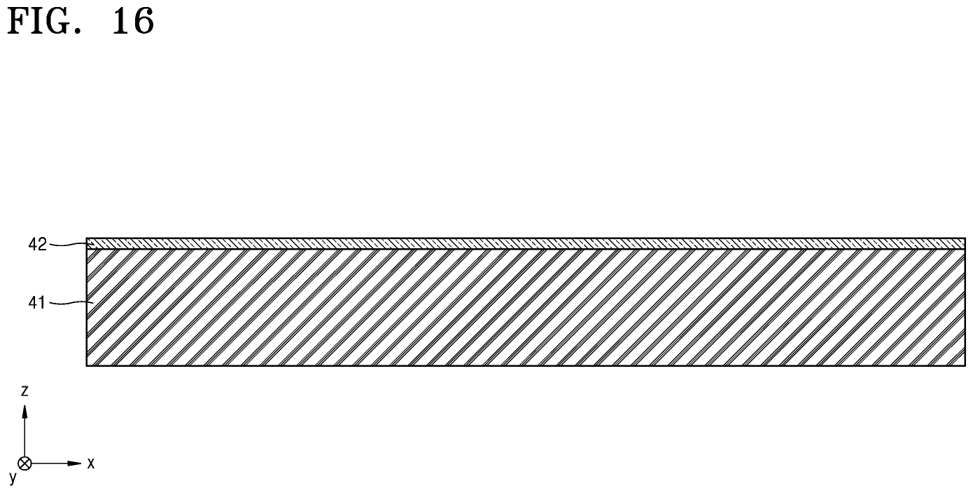

FIGS. 16 through 21 are schematic cross-sectional views of a mask assembly according to an embodiment.

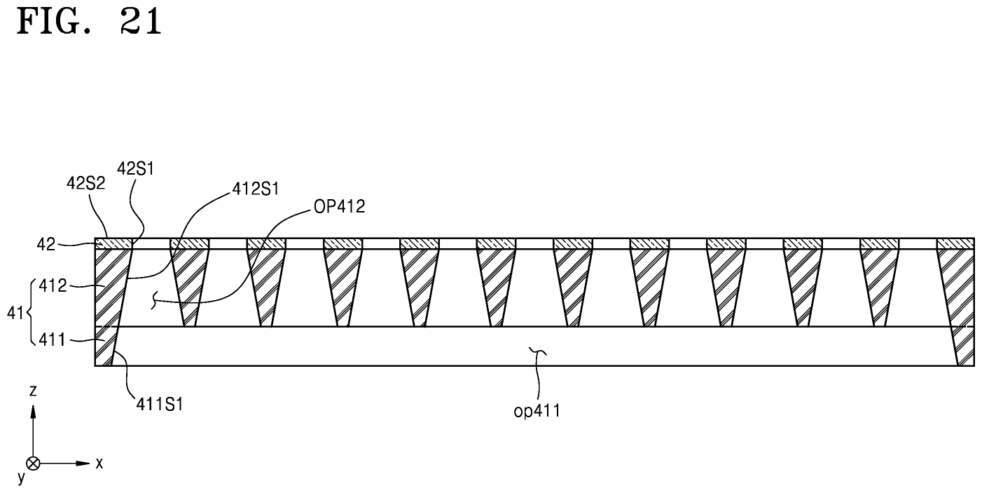

In FIGS. 16 and 21, the same reference numerals as those of FIGS. 14 and 15 denote the same members, and thus, repeated descriptions thereof are omitted.

Referring to FIGS. 16 to 21, an operation of disposing the mask assembly MA inside the chamber CH (see FIG. 1) is known.

Referring to FIG. 16, the disposing of the mask assembly MA may include disposing the second mask layer 42 on the first mask layer 41.

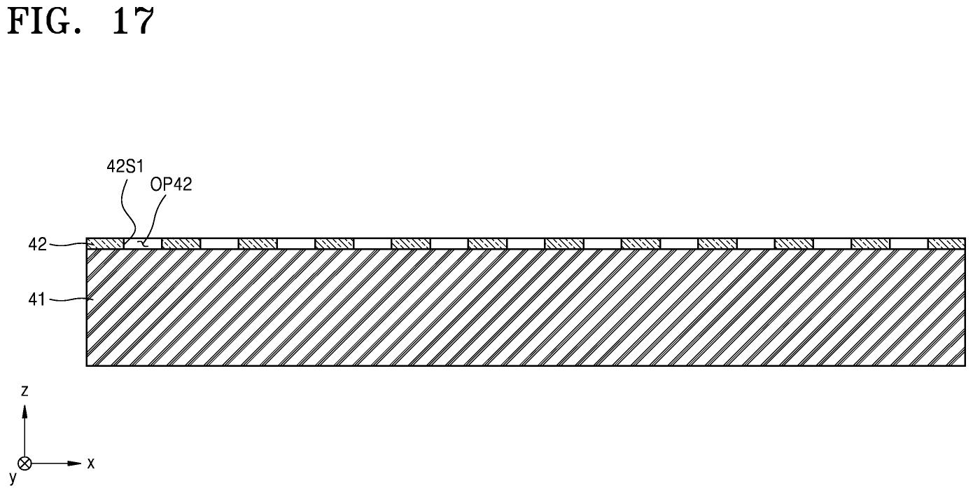

Referring to FIG. 17, the disposing of the mask assembly MA may include patterning the second mask layer 42 such that the plurality of second mask openings OP42 are disposed in the second mask layer 42.

While the second mask layer 42 is patterned, the 3-1 surface 42S1 may be formed. A portion of the upper surface of the first mask layer 41 may be exposed from the second mask layer 42 by the plurality of second mask openings OP42.

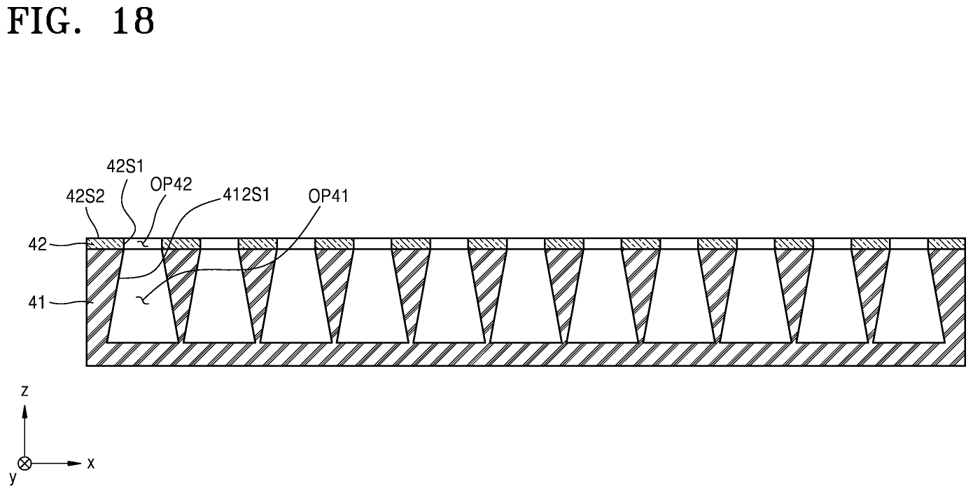

Referring to FIG. 18, the disposing of the mask assembly MA may include etching a portion of the first mask layer 41 overlapping the plurality of second mask openings OP42 to form the plurality of second portion openings OP412 (see FIG. 21) in the first mask layer 41.

For example, a portion of the first mask layer 41 may be dry-etched by an etching gas. In the etching a portion of the first mask layer 41, the second mask layer 42 may serve as a mask with respect to the etching gas. That is, the etching gas may pass through the plurality of second mask openings OP42 but not pass through the 3-2 surface 42S2 with the 3-1 surface 42S1 as a boundary. Accordingly, a portion of the first mask layer 41 overlapping the plurality of second mask openings OP42 may be etched and a plurality of second portion openings OP412 may be formed. The plurality of second portion openings OP412 may be spatially separated from one another. During this process, because a separate photoresist process is not required, the process is simplified, the time required may be shortened, and the manufacturing cost may be reduced. In this case, in a cross-sectional view, the width of each of the plurality of second portion openings OP412 may gradually increase with distance from the second mask layer 42.

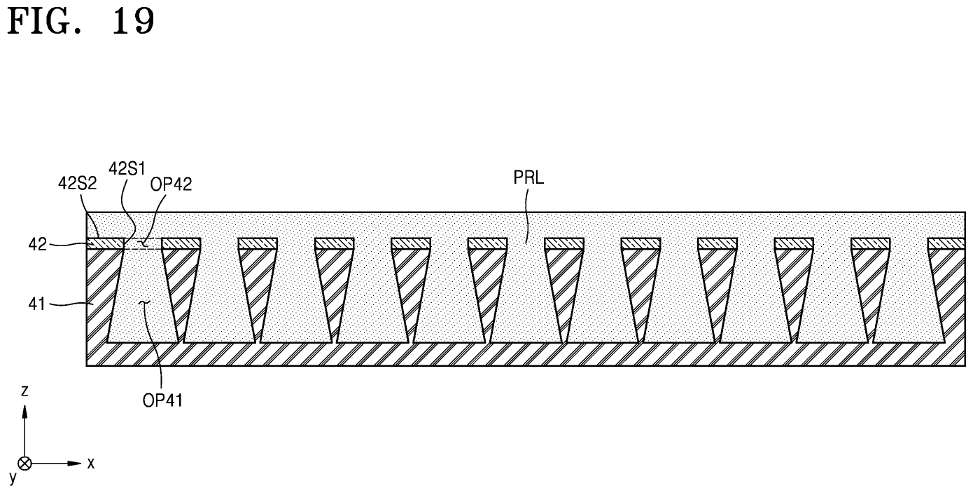

Referring to FIGS. 19 to 21, the disposing of the mask assembly MA may include forming an opening in the lower portion of the first mask layer 41.

First, referring to FIG. 19, the forming of the opening in the lower portion of the first mask layer 41 may include disposing a protective layer PRL such that at least a portion of the protective layer PRL is received in the plurality of second portion openings OP412 (see FIG. 21) and the plurality of second mask openings OP42. Here, the protective layer PRL may include a photoresist material.

In the disposing of the protective layer PRL, a portion of the protective layer PRL may be disposed in the first area ARE1. In addition, a portion of the protective layer PRL may be disposed on the second mask layer 42. The protective layer PRL may be in contact with the 3-1 surface 42S1 and the 3-2 surface 42S2.

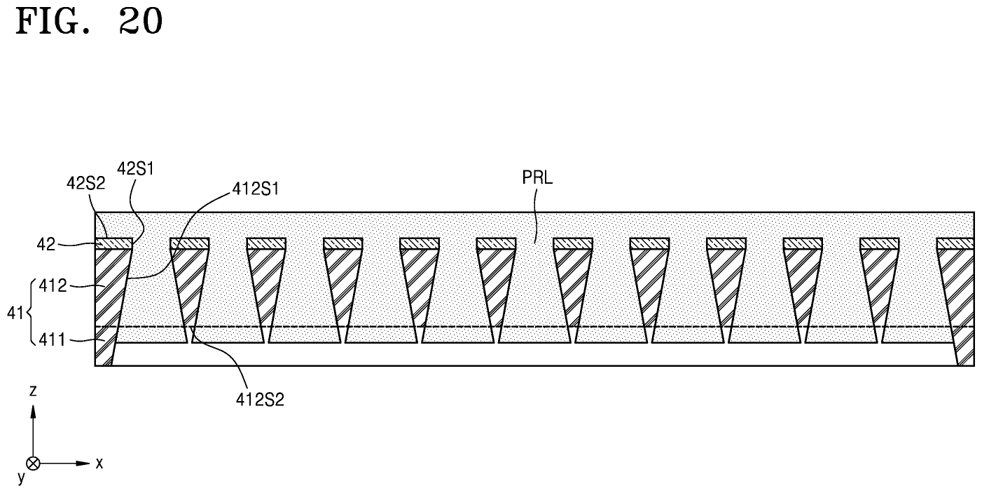

Referring to FIG. 20, the forming of the opening in the lower portion of the first mask layer 41 may include etching the lower portion of the first mask layer 41 to expose the lower surface of the protective layer PRL to the outside from the first mask layer 41.

During this process, a portion of the first mask layer 41 sealed by the protective layer PRL may be exposed to the outside from the protective layer PRL. Accordingly, a portion of the first mask layer 41 exposed from the protective layer PRL may be etched. The first mask layer 41 may be divided into the first portion 411 and the second portion 412 based on the etched lower surface of the first mask layer 41. A portion of the first mask layer 41 disposed under the etched lower surface of the first mask layer 41 is referred to as the first portion 411, and a portion of the first mask layer 41 disposed on the lower surface of the first mask layer 41 is referred to as the second portion 412. That is, the etched lower surface of the first mask layer 41 may be the 2-2 surface 412S2, which is the lower surface of the second portion 412.

Referring to FIG. 21, the forming of the opening in the lower portion of the first mask layer 41 may include removing the protective layer PRL.

The protective layer PRL may be removed from the first portion opening OP411, the plurality of second portion openings OP412, and the plurality of second mask openings OP42. The protective layer PRL may be removed by developing the protective layer PRL containing a photoresist material. Accordingly, the surfaces of the first portion 411, the second portion 412, and the second mask layer 42 that are adjacent to the first portion opening OP411, the second portion opening OP412, and second mask opening OP42 may be exposed. That is, the 1-1 surface 411S1, the 2-1 surface 412S1, the 3-1 surface 42S1, and the 3-2 surface 42S2 may be exposed.

According to an embodiment, manufacturing time and manufacturing cost of the mask assembly may be reduced, and transformation in the mask assembly may be reduced.

Effects of the disclosure are not limited to the above mentioned effects and other effects not mentioned may be clearly understood by those of ordinary skill in the art from the following claims.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. An apparatus for manufacturing a display apparatus, the apparatus comprising:
a chamber;
a mask assembly disposed inside the chamber to face a display substrate; and
a deposition source disposed inside the chamber to face the mask assembly and configured to supply a deposition material such that the deposition material passes through the mask assembly and is deposited on the display substrate,
wherein the mask assembly comprises:
a first mask layer including a silicon material, a first portion, and a second portion on the first portion, wherein a first portion opening is disposed in the first portion and a plurality of second portion openings are disposed in the second portion above the first portion opening; and
a second mask layer disposed on the first mask layer and including an inorganic material, the inorganic material having a plurality of second mask openings above the plurality of second portion openings, and
wherein, in a cross-sectional view, a width of each of the plurality of second portion openings increases with distance from the second mask layer.

2. The apparatus of claim 1, wherein, in a plan view, boundaries of at least two of the plurality of second portion openings are in contact with each other.

3. The apparatus of claim 1, wherein at least two of the plurality of second portion openings are spaced apart from each other.

4. The apparatus of claim 1, wherein the plurality of second portions are tapered.

5. The apparatus of claim 4, wherein a width of each of the plurality of second portions is between 0 μm and 14 μm, inclusive, at any point along its length.

6. The apparatus of claim 1, wherein, in a cross-sectional view, a slope angle of a lateral surface of the plurality of second portion openings is greater than 0° and less than or equal to 85° with respect to a plane that is parallel to a top surface of the mask.

7. The apparatus of claim 1, wherein the first portion and the second portion are integrated.

8. A mask assembly comprising:
a first mask layer including a silicon material, a first portion, and a second portion on the first portion, wherein a first portion opening is disposed in the first portion and a plurality of second portion openings are disposed in the second portion above the first portion opening; and
a second mask layer disposed on the first mask layer and including an inorganic material, the inorganic material having a plurality of second mask openings above the plurality of second portion openings, and
wherein, in a cross-sectional view, a width of each of the plurality of second portion openings increases with distance from the second mask layer.

9. The mask assembly of claim 8, wherein, in a plan view, boundaries of at least two of the plurality of second portion openings are in contact with each other.

10. The mask assembly of claim 8, wherein at least two of the plurality of second portion openings are spaced apart from each other.

11. The mask assembly of claim 8, wherein the plurality of second portions are tapered.

12. The mask assembly of claim 11, wherein a width of each of the plurality of second portions is between 0 μm and 14 μm, inclusive, at any point along its length.

13. The mask assembly of claim 8, wherein, in a cross-sectional view, a slope angle of a lateral surface of the plurality of second portion openings is greater than 0° and less than or equal to 85° with respect to a plane that is parallel to a top surface of the mask.

14. The mask assembly of claim 8, wherein the first portion and the second portion are integrated.

15. A method of manufacturing a display apparatus, the method comprising:
disposing a display substrate in a chamber;
disposing a mask assembly in the chamber; and
supplying, from a deposition source, a deposition material toward the mask assembly,
wherein the disposing of the mask assembly comprises:
disposing a second mask layer on a first mask layer;
patterning the second mask layer such that a plurality of second mask openings are disposed in the second mask layer;
forming a plurality of second portion openings in the first mask layer by etching the first mask layer through the plurality of second mask openings; and
forming an opening in a lower portion of the first mask layer.

16. The method of claim 15, wherein, in the etching of the portion of the first mask layer, a first space is formed in a lower portion of the plurality of second portion openings, and the first space is connected to the plurality of second portion openings.

17. The method of claim 15, wherein a plurality of second portion openings formed in the first mask layer are spatially separated from each other.

18. The method of claim 15, wherein the forming of the opening in the lower portion of the first mask layer comprises:
disposing a protective layer such that at least a portion of the protective layer is received in the plurality of second portion openings and the plurality of second mask openings;
etching a lower portion of the first mask layer to expose a lower portion of the protective layer; and
removing the protective layer.

19. The method of claim 18, wherein, the disposing of the protective layer comprises disposing a portion of the protective layer in a first space in a lower portion of the plurality of second portion openings.

20. The method of claim 18, wherein the etching of the lower portion of the first mask layer to expose the lower portion of the protective layer comprises exposing a portion of the first mask layer by removing the protective layer.
